(19) United States
(12) Patent Application Publication
(10) Pub. No.: US 2012/0034733 A1
(43) Pub. Date: Feb. 9, 2012

(54) SYSTEM AND METHOD FOR FABRICATING THIN-FILM PHOTOVOLTAIC DEVICES

(75) Inventors: Piero Sferlazzo, Marblehead, MA (US); Thomas Michael Lampros, Cambridge, NY (US)

(73) Assignee: Aventa Technologies LLC, Danvers, MA (US)

(21) Appl. No.: 13/101,538

(22) Filed: May 5, 2011

Related U.S. Application Data
(63) Continuation-in-part of application No. 12/850,939, filed on Aug. 5, 2010.

(51) Int. Cl. H01L 31/0272; C23C 16/06

(52) U.S. Cl. 438/95; 118/719; 257/E31.008

(57) ABSTRACT

Described are a system and a method for depositing a thin film on a substrate. In some embodiments, the system includes a substrate transport system to transport a plurality of discrete substrates, such as glass substrates or wafers, along a closed path. The system also includes a metal deposition zone, a selenization zone and a cooling chamber each disposed on the closed path. During transport along the closed path, the metal deposition zone deposits a layer of a composite metal onto the discrete substrates and the selenization zone selenizes the layer of the composite metal. The cooling zone cools the discrete substrates prior to a subsequent pass through the metal deposition zone and the selenization zone.

### RELATED APPLICATION

This application is a continuation-in-part application of U.S. patent application Ser. No. 12/850,939, titled “System and Method for Fabricating Thin-Film Photovoltaic Devices” and filed Aug. 5, 2010.

### FIELD OF THE INVENTION

The invention relates generally to the manufacture of electronic devices. More particularly, the invention relates to a method and a system for forming photovoltaic light absorbing Chalcopyrite compound layers of copper indium gallium diselenide (CIGS) on substrates for fabrication of thin film solar cells and modules.

### BACKGROUND OF THE INVENTION

Thin film solar cells have attracted significant attention and investment in recent years due to the potential for lowering the manufacturing costs of photovoltaic solar panels. Most solar panels are fabricated from crystalline silicon and polycrystalline silicon. While silicon-based technology enables fabrication of high efficiency solar cells (up to 20% efficiency), material costs are high due the embodied energy to refine and grow the bulk silicon ingots of silicon from silicon dioxide. In addition, sawing these ingots into wafers results in approximately 50% of the material being wasted. These solar cells are the primary component of the majority of solar panels made and sold today. Presently, silicon solar cells are approximately 90 μm thick. In contrast, thin film solar cells include layers that are approximately 1 μm to 3 μm thick and are deposited directly onto low cost substrates. Among the most popular materials used are amorphous silicon, copper indium diselenide and its alloys with gallium or aluminum (CIS, CIGS, CIAS) and cadmium telluride (CdTe).

Typically, amorphous silicon has the lowest manufacturing costs in terms of cost per unit of power produced, but the efficiencies of the solar cells are generally less than 10% which is low relative to the efficiencies of other materials. CIGS and CdTe cells have higher efficiencies and in the lab have achieved efficiencies approaching and sometime exceeding the efficiencies of silicon-based cells. Small area laboratory-scale cells have demonstrated efficiencies in excess of 20% and 18% for CIGS and CdTe, respectively; however, the transition to volume manufacturing and larger substrates is difficult and substantially lower efficiencies are realized.

Recently, CIGS solar cells have been produced in the laboratory and in production using a three phase co-evaporation process. In this process effusion sources of copper (Cu), indium (In) and gallium (Ga) evaporate at the same time in the presence of a selenium source. In this manner, deposition and selenization occur in a single step as long as the substrate temperature is maintained between about 400° C. and 600° C. Typically, higher temperatures result in higher efficiencies; however, not all substrates are compatible with higher temperatures. Sodium is often added to the mixture of sources and has been shown to enhance minority carriers and to improve voltage. Sodium may also passivate surfaces and grain boundaries. The deposition is repeated three times. For each deposition, the relative concentrations of copper, indium and gallium are changed, thus producing a graded compositional structure that can be more effective at absorbing and converting incident light into electrical power.

Scaling the three phase co-evaporation process to production levels is complicated due to a number of fundamental difficulties. First, effusion sources require high power consumption at production scale because the sources need to be maintained at temperatures as high as 1,500° C. At these high temperatures many materials are extremely reactive. Longevity of system components is decreased and process control and maintenance are difficult. Thus costs associated with production systems are high and downtime can be significant.

The substrate temperature is high during the selenization process. Consequently, the selenium residence time on the substrate surface is small and the selenium utilization efficiency is low. Selenium utilization and unwanted accumulation in various regions of the process chamber make the co-evaporation process difficult to manage in a production environment.

A number of groups have fabricated solar cells using the co-evaporation process while other groups have adopted production-compatible alternatives. One common alternative approach is based on a two-step process that typically includes depositing the metals (copper, indium and gallium) on a substantially cold substrate, that is, a substrate near or at ambient temperature. The deposited metals are then selenized in a hydrogen selenide (H₂Se) gas or in a selenium vapor from a solid source. An ambient temperature is maintained between about 250° C. and 600° C.

The metals are typically deposited by electroplating, sputter deposition or printing. The metal deposition step is often followed by a cold deposition of selenium prior to the substrate entering a selenization furnace. The selenium deposition thickness is in the range of approximately 1 μm to 2 μm. By creating a selenium layer on top of the CIG layer, indium is prevented from diffusing out of the metal layer during the ramping of the furnace temperature. The temperature ramp can be of long duration, especially for thick glass substrates; however, for thin flexible foils, rapid temperature ramps (e.g., 10° C./s) are possible and are significant in reducing the problem of indium depletion. This two-step process is more controllable and easier to implement in system equipment in comparison to the co-evaporation technique; however, the resulting efficiencies generally are lower by 2% to 4%. The lower efficiencies are due to non-ideal grain formation and to the segregation of gallium and indium during the selenization step. Typically, gallium diffuses toward the back electrode to form a CuGaSe compound, while indium diffuses toward the barrier layer to form an indium rich compound near the front surface of the cell. Sulfur is sometimes added to the selenium in the furnace to compensate for this diffusion problem by increasing the bandgap of the material at the surface; however, the resulting absorbing layer is not a true CuInGaSe₂ compound and the known advantages of adding gallium to CIS are moderated.

A hybrid technique has been used to implement a co-sputtering/selenization; however, selenium poisoning of the sputtering targets can occur and the hot substrate results in poor selenium utilization. Thus this technique is generally more difficult to control than the co-evaporation process.

### SUMMARY

In one aspect, the invention features a system for depositing a thin film on a substrate. The system includes a substrate transport system to transport a plurality of discrete substrates along a closed path. The system also includes a metal deposition zone, a selenization zone and a cooling chamber. The metal deposition zone is disposed on the closed path and is configured to deposit a layer of a composite metal onto the discrete substrates during passage through the metal deposition zone. The selenization zone is disposed on the closed path and receives the discrete substrates after they pass through the metal deposition zone. The cooling chamber is disposed along the closed path and receives the discrete substrates after they pass through the selenization zone. The cooling chamber is configured to cool the discrete substrates prior to a subsequent pass of the discrete substrates through the metal deposition zone and the selenization zone.

In another aspect, the invention features a system for depositing a thin film on a substrate. The system includes a substrate transport system to transport a plurality of discrete substrates along a path having a load end and an unload end. The system also includes a plurality of metal deposition zones, a plurality of selenization zones and a plurality of cooling zones. The metal deposition zones are disposed on the path and each metal deposition zone is configured to deposit a layer of a composite metal onto the discrete substrates during passage through the metal deposition zone. Each selenization zone is disposed on the path and receives the discrete substrates after they pass through a respective one of the metal deposition zones. Each cooling zone is disposed on the path and receives the discrete substrates after they pass through a respective one of the selenization zones.

In another aspect, the invention features a method of depositing a thin film on a substrate. The method includes depositing a layer of a composite metal onto a discrete substrate during transport through a metal deposition zone. The discrete substrate is transported to a selenization zone. During transport of the discrete substrate through the selenization zone, a selenium layer is deposited onto the layer of the composite metal and the discrete substrate is heated to selenize the layer of the composite metal. A determination is made as to whether or not the layer of the composite metal deposited onto the discrete substrate is a last deposition layer. If it is determined that the layer of the composite metal deposited onto the discrete substrate is not the last deposition layer, the above method steps prior to the determination step are repeated.

### BRIEF DESCRIPTION OF THE DRAWINGS

The above and further advantages of this invention may be better understood by referring to the following description in conjunction with the accompanying drawings, in which like numerals indicate like structural elements and features in the various figures. For clarity, not every element may be labeled in every figure. The drawings are not necessarily to scale, emphasis instead being placed upon illustrating the principles of the invention.

FIG. 1 is an illustration of an embodiment of an apparatus for depositing a copper indium gallium diselenide film on a web according to the invention.

FIG. 2 is a flowchart representation of an embodiment of a method of depositing a copper indium gallium diselenide film on a web according to the invention.

FIG. 3 illustrates a selenization furnace for the apparatus of FIG. 1 that includes three independently controlled heating zones according to an embodiment of the invention.

FIG. 4 is a schematic illustration of a selenium trap for the apparatus of FIG. 1 according to an embodiment of the invention.

FIG. 5 is a block diagram of an embodiment of a system for deposition of a thin film on a substrate according to the invention.

FIG. 6A and FIG. 6B are a perspective view and a top view, respectively, of an embodiment of a system for deposition of a thin film on a substrate according to the invention.

FIG. 7 is a flowchart representation of an embodiment of a method of depositing a thin film on a substrate according to the invention.

FIG. 8 is a block diagram of another embodiment of a system for deposition of a thin film on a substrate according to the invention.

### DETAILED DESCRIPTION

The systems and methods of the present invention may include any of the described embodiments or combinations of the described embodiments in an operable manner. In brief overview, the systems and methods of the invention enable the deposition of a CIGS thin film by sputtering deposition on metal and plastic thin foils and discrete substrates. As used herein, a discrete substrate means an individual component such as a glass plate, a glass panel or a wafer. The flexibility and bandgap engineering advantages of co-evaporation techniques are realized without the production scaling problems of prior art co-evaporation systems. CIGS devices having high conversion efficiencies are manufactured using a multistep process that includes sputtering and selenization sequences. First, a substantially thin metal layer of CuInGa (e.g., approximately 0.15 μm thickness) is deposited onto a cold web substrate or a discrete substrate. For example, the substrate temperature in the sputtering region is preferably as low as practical (e.g., ambient temperature) but may be up to 300° due to operation of the sputtering equipment. Subsequently, selenization occurs in a selenization furnace which is in-line with the sputtering system. The process is repeated a number of times until a desired thickness of the absorber layer is attained (e.g., approximately 2.5 μm). The composition of each incremental thin metal layer can be varied throughout the full deposition process to achieve desired bandgap gradients and other film properties. Segregation of gallium and indium is substantially reduced or eliminated because each incremental layer is selenized before the next incremental layer is deposited. This epitaxial growth process (or layer-by-layer method) by a co-sputtering/selenization process eliminates the problems associated with the presence of selenium in the sputtering chamber. The process can be implemented in a roll-to-roll production system to deposit CIGS films on metal and plastic foils. Alternatively, the process can be implemented in a discrete substrate production system to deposit CIGS films on discrete substrates such as glass substrates and wafers.

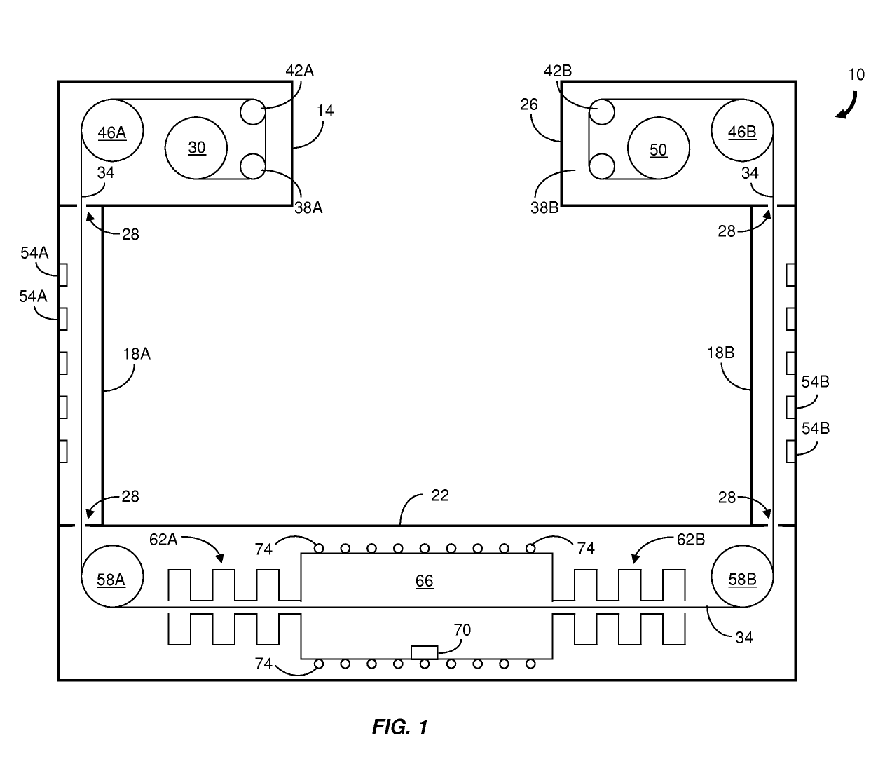

Referring to FIG. 1, an embodiment of an apparatus 10 for deposition of a copper indium gallium diselenide film on a web includes a payout zone 14, a first sputtering zone 18A, a selenization zone 22, a second sputtering zone 18B and a take-up zone 26. As used herein, the term zone means one or more chambers that can be operated to perform a specific process. The sputtering zones 18 and selenization zone 22 are coupled to respective pump systems (not shown) so that the vacuum level for the zones can be independently controlled. Low conductance slits 28 between the zones achieves a high degree of vacuum isolation between neighboring zones.

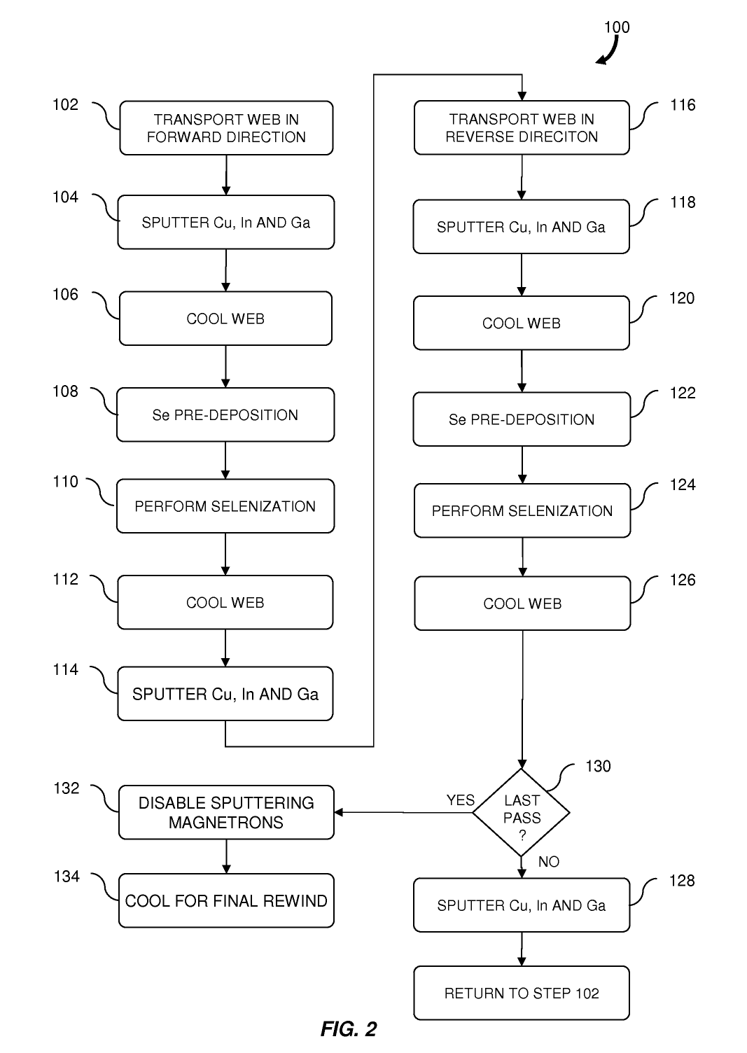

The payout zone 14 includes a payout roll 30 of web material 34, such as a thin plastic or metal foil, that is dispensed and transported through the other zones. The payout zone 14 also includes an idler roll 38A, a load cell 42 to maintain web tension and a cooling roll 46A that has a substantially larger diameter than the other rolls. The take-up zone 26 includes a take-up roll 50 to receive the web 34 after passage through the other zones. The take-up zone also includes rolls 38B, 42B and 46B that function as counterparts to rolls in the payout zone 14. At least one of the payout roll 30 and the take-up roll 50 is coupled to a web transport mechanism as is known in the art that enables the web 34 to pass through the intervening zones. The operation of the payout roll 30 and the take-up roll 50 can be reversed, that is, the payout roll 30 can also perform as a take-up roll and the take-up roll 50 can perform as a payout roll when the web is transported in a reverse direction (right to left) as described below with respect to FIG. 2.

The first sputtering zone 18A is a chamber having a plurality of sputtering magnetrons 54. The magnetrons 54 can be planar magnetrons or rotating cylindrical magnetrons as are known in the art. Target material composition for each magnetron 54 can vary relative to the materials of the targets for the other magnetrons 54 to achieve a graded composition structure in the resulting film.

The selenization zone 22 includes two cooling rolls 58 that surround two differentially pumped selenium traps 62 and a selenization furnace 66 having a selenium source 70. A multiple zone resistive heater comprising heating components 74 enables the furnace temperature along the web path through the selenization furnace 66 to vary.

FIG. 2 shows a flowchart representation of an embodiment of a method 100 of depositing a copper indium gallium diselenide film on a web according to the invention. Referring to FIG. 1 and FIG. 2, the web 34 is transported (step 102) from the payout zone 14 into the first sputtering zone 18A where the pressure is maintained below 0.01 Torr. During passage through the sputtering zone 18A, a deposition (step 104) of an incremental layer of copper, indium and gallium occurs. The targets of each magnetron 54 can have a variety of compositions. For example, each target material can be copper, indium, or alloys of each as with gallium or aluminum. The thickness of the incremental layer deposited on the web 34 during passage through the sputtering zone 18A varies according to different process parameters such as the web transport speed. By way of example, the thickness of the deposited incremental layer can be between 100 Å and 2000 Å.

After the first incremental layer is deposited, the web 34 enters the selenization zone 22. The web 34 first passes over a cooling roll 58A to cool (step 106) the web 34 before it enters a multistage differentially pumped selenium trap 62A. The trap 62A prevents selenium that may escape from the selenization furnace 66 from entering the sputtering zone 18A. The web 34 is pre-coated (step 108) with a thin layer (e.g., approximately 0.5 μm) of selenium in the trap 62A before entering the furnace 66. The relatively cold web temperature (e.g., less than 150° C.) allows selenium to condense on the web 34 as it moves through the trap 62. The web 34 then moves through the furnace 66 where selenization occurs (step 110) at a pressure that is substantially higher than the sputter pressure and at a temperature between 250° C. and 600° C. For example, the selenization can occur at a pressure in a range between 0.0001 Torr and 10 Torr. The pre-coating of selenium is advantageous in preventing indium depletion when the web temperature increases rapidly inside the furnace 66.

After exiting the furnace 66, the web 34 is cooled (step 112) to a lower temperature (e.g., less than 100° C.) by a second cooling roll 58B. The web 34 then passes through the second sputtering zone 18A where a second incremental layer of copper indium gallium of varying composition is deposited (step 114).

Once most of the web material from the payout roll 30 has been processed by transport in the forward direction, that is, dispensed from the payout roll 30 through the intervening zones and accumulated onto the payout roll 50, the deposition method 100 continues by transporting the web 34 in the reverse direction (step 116). While the web 34 moves back through the intervening zones, the original payout zone 14 functions as a take-up zone and the original take-up zone 26 functions as a payout zone. The web 34 passes through the sputtering and selenization zones 18 and 22 in reverse order to execute a sequence of steps (steps 118 to 128) that is reversed to the sequence of steps used during the forward transport. Thus a third incremental layer of copper indium gallium is deposited (step 118) on top of the second incremental layer in the second sputtering zone 18B before the second selenium pre-deposition occurs (step 122). Selenization is performed (step 124) during passage through the furnace 66 before a fourth incremental layer of copper indium gallium (step 128) is deposited onto the web 34.

Except for the first pass of the web 34 through the first sputtering zone 18A, it can be seen that selenization is performed after two consecutive passes of the web 34 through the same sputtering zone 18A or 18B. Thus two incremental layers are formed on the web 34 before selenization is performed. Advantageously, in some embodiments the power densities for the sputtering magnetrons can be reduced relative to the power densities for a single pass deposition of an incremental layer prior to selenization. In addition, because the power densities can be changed between passes, the composition of each layer can be changed without the need to change targets.

Forward and reverse transport processing are repeated a number of times until a CuInGaSe₂ film of a desired total thickness is deposited onto the web 34 (as determined at step 130). It should be noted that at the end of the process, the magnetrons in the sputtering zone 18A or 18B used after the last passage through the selenization furnace 66 are disabled (step 132) and the web 34 is cooled before a final rewind (step 134).

The iterative selenization implemented throughout the process reduces or eliminates the gallium and indium segregation problem that is common to two-step CIG processes because the first incremental layer and the pairs of consecutive incremental layers from round-trip passage through a sputtering zone 18 are selenized before the next pair of incremental layers is deposited. Moreover, because the layers to be selenized are thin, the time required for the web 34 to pass through the selenization furnace 66 can be short. Consequently, the web transport speed can be high. The multiple pass forward and reverse process and high web transport speed permit efficient construction of a multilayer structure having a varying composition and bandgap.

Although the apparatus 10 and method 100 described above relate primarily to a configuration having a single selenization furnace 66 and a pair of sputtering zones 18, it should be recognized that other configurations are contemplated according to principles of the invention. For example, multiple selenization furnaces and additional sputtering zones can be employed to enable multiple layers to be deposited and subsequently selenized while the web is transported in a single direction.

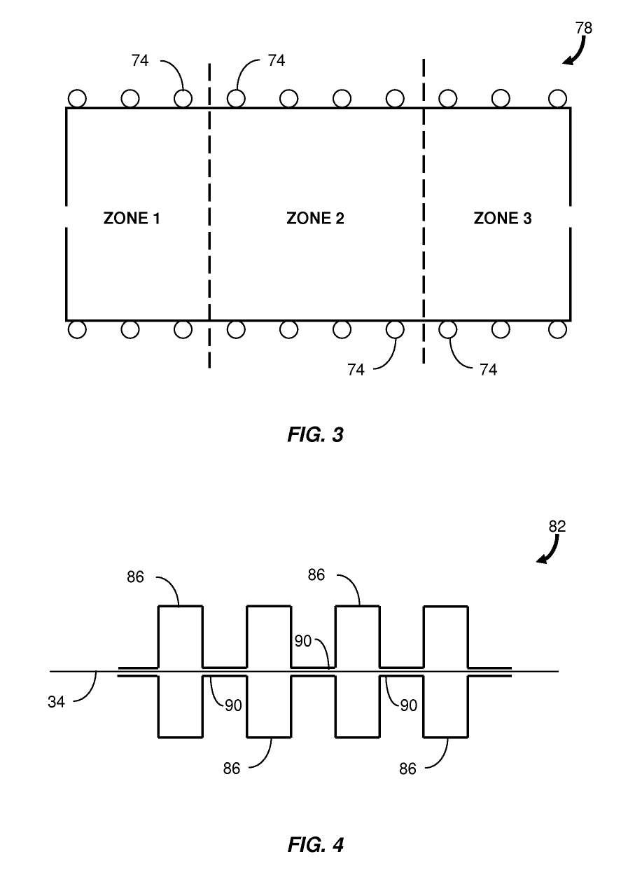

In some embodiments the selenization furnace 66 has multiple heating zones. FIG. 3 shows a selenization furnace 78 having three independently controlled heating zones. For example, ZONE 1 has a higher power density than ZONE 2 and ZONE 3 when the web 34 is transported from left to right in the figure. Conversely, ZONE 3 has a higher power density than the other zones when the web 34 moves in the opposite direction, that is, from right to left. By varying the temperature of the zones in this manner, a more rapid heating of the web 34 occurs as it enters the furnace 78. In some embodiments, the set temperature for the furnace 78 varies for each pass.

Various types of selenium traps can be used. For example, different schemes based on differential pumping to gradually transition from a higher pressure region to a lower pressure region as are known in the art can be used.

FIG. 4 is a schematic representation of an embodiment of a selenium trap 82 according to the invention. The trap 82 includes alternating plenums 86 and narrow gaps 90 of low conductance. The plenums 86 are maintained at a low temperature, for example, at a temperature between 0° C. and 20° C., while the gaps 90 are maintained at a substantially higher temperature, for example, 200° C. or greater. During operation, selenium does not accumulate on the hot surfaces of the gaps 90 but does accumulate on the cold surfaces of the plenums 86. In a preferred embodiment, the selenium pressure is reduced by a factor between approximately 5 and 10 for each gap 90 and neighboring plenum 86 with increasing distance from the selenization furnace 66. The numbers of gaps 90 and plenums 86 are preferentially determined by the desired pressure differential.

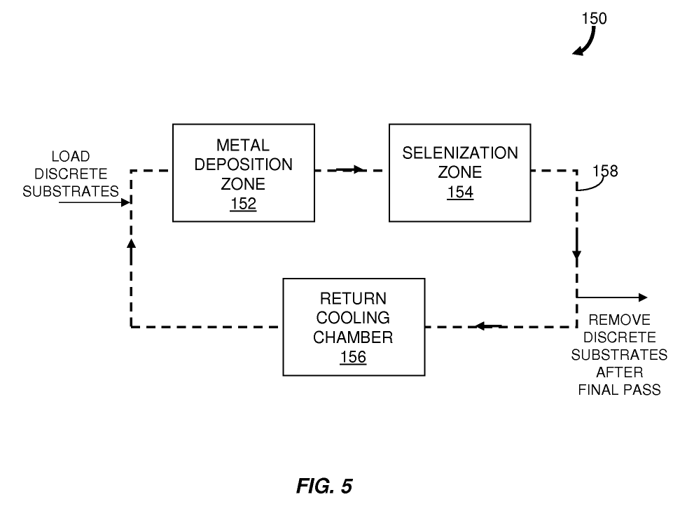

FIG. 5 is a functional block diagram of an embodiment of a system 150 for deposition of a thin film on a substrate. By way of example, the system 150 can be used to deposit a copper indium gallium diselenide film on a discrete substrate. The system 150 includes a metal deposition zone 152, a selenization zone 154 and a return cooling chamber 156. The system 150 also includes a substrate transport system (not shown) that transports a number of discrete substrates along a closed path 158 that passes through the zones 152, 154 and the return cooling chamber 156. The metal deposition zone 152 is configured to deposit a layer of a composite metal onto the discrete substrates as they pass through the zone. As used herein, a closed path means a path which has no beginning and no end. For example, a closed path can be a rectangular path or circular path along which the substrates are transported.

The metal deposition zone 152 can be a sputtering zone as is known in the art. The selenization zone 154 receives the discrete substrates after they pass through the metal deposition zone 152. Except for the final pass through the system 150, the return cooling chamber 156 receives the discrete substrates after they exit the selenization zone 154. The return cooling chamber 156 cools the discrete substrates before the substrates arrive at the metal deposition zone 152 for deposition of the next incremental layer.

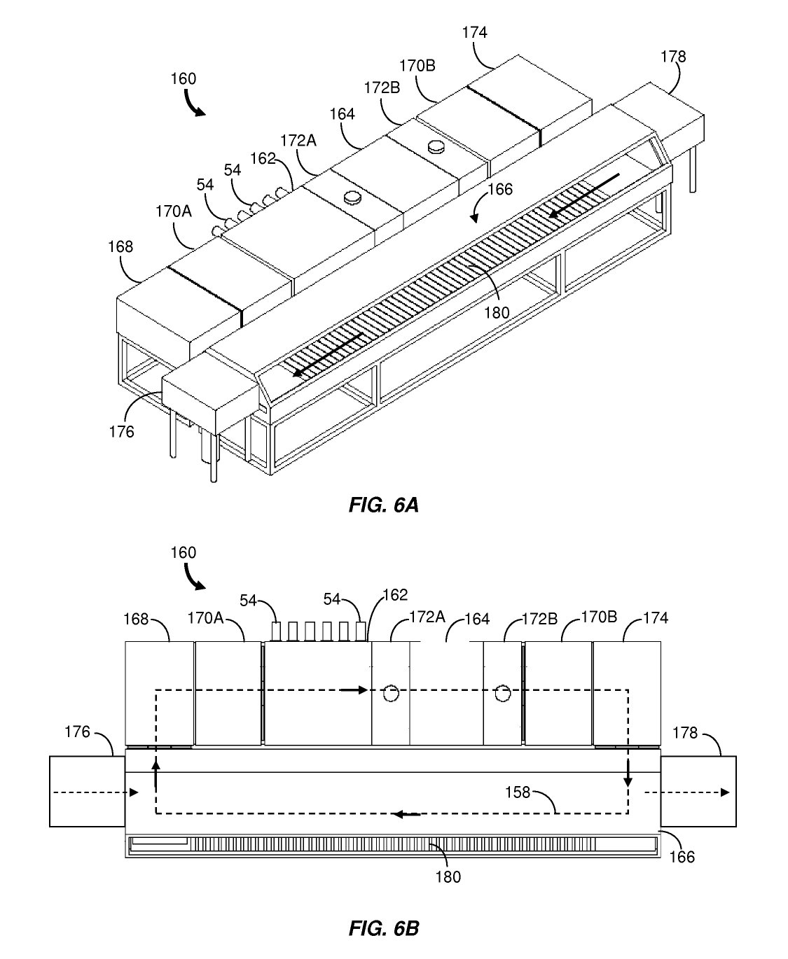

FIG. 6A and FIG. 6B are a perspective view and a top view, respectively, of an embodiment of a system 160 for deposition of a thin film on a substrate. The system 160 includes the system components shown in the functional block diagram of FIG. 5 in the form of a sputtering chamber 162, a selenization furnace 164 and selenium traps 172A and 172B, and a cooling chamber 166. For convenience, a portion of the top and side of the cooling chamber 166 are removed from FIG. 6A and FIG. 6B so that the substrate transport system 180 inside the cooling chamber 166 is visible. In various embodiments, the substrate transport system 180 includes one or more belt or roller type conveyance mechanisms to move the discrete substrates along the closed loop path 158.

The deposition system 160 also includes two load locks 168 and 174, and buffer stations 170A and 170B. In the illustrated embodiment, a load mechanism 176 (e.g., a robotic load station) retrieves discrete substrates from a supply of discrete substrates and places them onto a substrate transport system. Once the final pass through the sputtering chamber 162 and selenization furnace 164 is completed, an unload mechanism 178 (e.g., a robotic unload station) removes the discrete substrates from the substrate transport system 180 after the discrete substrates emerge from the exit load lock 174.

The sputtering chamber 162 includes a plurality of sputtering magnetrons 54, such as planar magnetrons or rotating cylindrical magnetrons. In some embodiments in which a copper indium gallium diselenide film is deposited, the targets are composed of copper, indium, or alloys of each with gallium or aluminum. In various embodiments, the target material composition for each magnetron 54 varies with respect to the target material composition for the other magnetrons 54 so that a graded composition structure is achieved in the deposited film.

In various embodiments, the selenization furnace 164 operates in a temperature range of about 250° C. to 600° C. Optionally, the selenization furnace 164 can include a multiple zone resistive heater so that the temperature along the closed path 158 within the furnace varies. The two selenium traps 172 on each side of the selenization furnace 164 preferably are differentially pumped multistage traps. The selenium traps 172 prevent selenium that may escape the furnace 164 from entering the sputtering chamber 162 or adversely affecting other system components.

The sputtering chamber 162 and selenization furnace 164 are coupled to separate pump systems (not shown) to permit the vacuum levels for each of these zones to be independently controlled. Low conductance apertures, or substrate passages, at locations between system components and selenium traps 172 results in a high degree of vacuum isolation and enables more efficient vacuum control.

The cooling chamber 166 operates at atmospheric pressure is configured to reduce the temperature of the discrete substrates prior to a subsequent pass through the sputtering chamber 162 and selenization furnace 164. Various forms of coolers may be employed. In one embodiment, a cold plate extending at least along a portion of the length of the cooling chamber 166 is mounted above the substrate path such that discrete substrates passing underneath are cooled by atmospheric conduction.

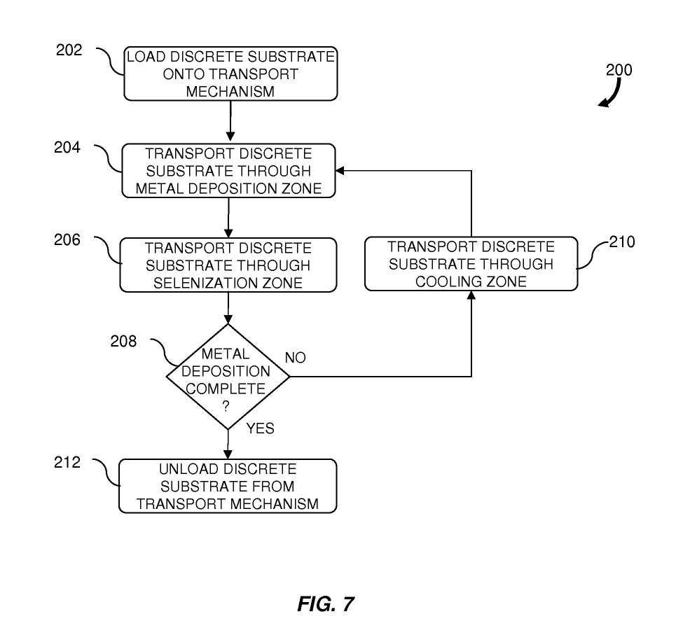

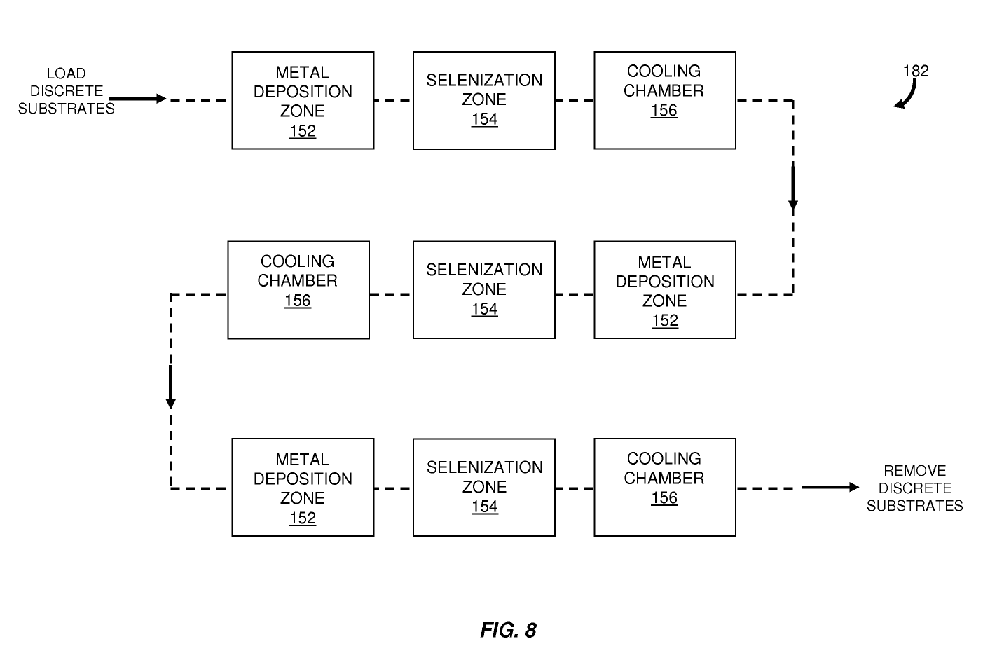

FIG. 7 is a flowchart representation of an embodiment of a method 200 of depositing a thin film, for example, a copper indium gallium diselenide film, on a substrate according to the invention. Referring to FIGS. 6A, 6B and 7, discrete substrates are loaded (step 202) on or into the substrate transport system 180 which transports the substrates into the load lock 168. After the substrate environment is reduced to the appropriate vacuum level, the discrete substrates exit the load lock 168, pass through the first buffer station 170A and pass (step 204) through the sputtering chamber 162 where a layer of composite metal is deposited. The discrete substrates continue along the closed path and are transported (step 206) through the first selenium trap 172A, the selenization furnace 164 and the second selenium trap 172B. Subsequently, the discrete substrates pass through the second buffer station 170B before entering the exit load lock 174 where the substrate environment is returned to atmospheric pressure. If it is determined (step 208) that further incremental deposition layers are to be deposited, the discrete substrates that leave the exit load lock 174 are transported (step 210) through the cooling chamber 166 before subsequent deposition and selenization occur (steps 204 and 206). If it is determined (step 208) that the last incremental layer has been deposited, the discrete substrates exit the exit load lock 174 and are unloaded (step 212) or removed from the substrate transport system 180. The number of passes that the discrete substrates make along the closed path can be based on a variety of parameters, for example, the desired structure and thickness of the deposited films and the transport speed.

Although the embodiments of a system for discrete substrates described above relate to transporting the discrete substrates along a closed path, in alternative embodiments the system transports discrete substrates along an open path, that is, a path that includes two ends: a load end and an unload end. FIG. 8 is a functional block diagram of an embodiment of one such system 182 where each discrete substrate passes through a group of system components that includes a metal deposition zone 152, a selenization zone 154 and a cooling chamber 156. Unlike the system 150 of FIG. 5, each additional incremental layer is deposited by a single pass through a subsequent group of system components that includes a metal deposition zone 152, selenization zone 54 and cooling chamber 156. By way of example, each group of system components can include a cooling chamber 166 and the various components between the load locks 168 and 174, inclusive, as illustrated in FIGS. 6A and 6B. Although the embodiment illustrated in FIG. 8 shows three groups of system components, any number of groups that is greater than or equal to two can be used. It should be understood that the number of incremental layers that can be deposited on the discrete substrate is equal to the number of groups of system components. In still other embodiments, a system can include a combination of one or more closed paths and one or more open paths with each path having at least one group of system components.

While the invention has been shown and described with reference to specific embodiments, it should be understood by those skilled in the art that various changes in form and detail may be made therein without departing from the spirit and scope of the invention as recited in the accompanying claims.

What is claimed is:

1. A system for depositing a thin film on a substrate, comprising:
a substrate transport system to transport a plurality of discrete substrates along a closed path;
a metal deposition zone disposed on the closed path and configured to deposit a layer of a composite metal onto the discrete substrates during passage through the metal deposition zone;
a selenization zone disposed on the closed path to receive the discrete substrates after passing through the metal deposition zone; and
a cooling chamber disposed along the closed path to receive the discrete substrates after passing through the selenization zone, the cooling chamber configured to cool the discrete substrates prior to a subsequent pass of the discrete substrates through the metal deposition zone and the selenization zone.

2. The system of claim 1 wherein the metal deposition zone is a sputtering zone.

3. The system of claim 2 wherein the sputtering zone comprises a plurality of magnetrons, the system further comprising a target material for each of the magnetrons, each of the target materials having a composition comprising one of copper indium gallium, copper gallium and copper indium.

4. The system of claim 3 wherein the target material for each magnetron in one of the sputtering zones has a composition that is different from a composition of the target material for each of the other magnetrons in the sputtering zone.

5. The system of claim 1 wherein the layer of the composite metal is a copper indium gallium layer.

6. The system of claim 1 wherein the selenization zone comprises:
a selenization furnace;
a first selenium trap disposed between the metal deposition zone and the selenization furnace; and
a second selenium trap disposed between the selenization furnace and the cooling chamber.

7. The system of claim 6 wherein the selenization furnace is configured to maintain a temperature in a range of approximately 250° C. to 600° C.

8. The system of claim 6 further comprising:
a first low conductance aperture disposed between the metal deposition zone and the first selenium trap; and
a second low conductance aperture disposed between the second selenium trap and the cooling chamber.

9. The system of claim 6 wherein the first and second selenium traps are differentially pumped.

10. The system of claim 6 wherein the selenization furnace has a heater comprising a plurality of zones each having a temperature that is independently controlled.

11. The system of claim 1 further comprising:
a load mechanism disposed along the closed path to load the discrete substrates onto the substrate transport system; and
an unload mechanism disposed along the closed path to remove the discrete substrates from the substrate transport system.

12. The system of claim 1 wherein the discrete substrates comprise glass substrates.

13. A system for depositing a thin film on a substrate, comprising:
a substrate transport system to transport a plurality of discrete substrates along a path having a load end and an unload end;
a plurality of metal deposition zones disposed on the path, each metal deposition zone configured to deposit a layer of a composite metal onto the discrete substrates during passage through the metal deposition zone;
a plurality of selenization zones, each selenization zone disposed on the path to receive the discrete substrates after passing through a respective one of the metal deposition zones; and
a plurality of cooling zones, each cooling zone disposed on the path to receive the discrete substrates after passing through a respective one of the selenization zones.

14. The system of claim 13 further comprising:
a load mechanism disposed at the load end of the path to load the discrete substrates into the substrate transport system; and
an unload mechanism disposed at the unload end of the path to remove the discrete substrates from the substrate transport system.

15. A method of depositing a thin film on a substrate, the method comprising:
(a) depositing a layer of a composite metal onto a discrete substrate during transport through a metal deposition zone;
(b) transporting the discrete substrate to a selenization zone;
(c) depositing a selenium layer onto the layer of the composite metal during transport of the discrete substrate through the selenization zone;
(d) heating the discrete substrate during transport through the selenization zone to selenize the layer of the composite metal;
(e) determining if the layer of the composite metal deposited onto the discrete substrate is a last deposition layer;
(f) repeating steps (a) to (d) if a determination is made that the layer of the composite metal deposited onto the discrete substrate is not the last deposition layer.

16. The method of claim 15 further comprising cooling the discrete substrate after step (e) if a determination is made that the layer of the composite metal deposited onto the discrete substrate is not a last deposition layer.

17. The method of claim 15 wherein the layer of the composite metal comprises a copper indium gallium layer.

18. The method of claim 17 wherein a plurality of layers of the composite metal are deposited and wherein a relative composition of copper, indium and is different for at least two of the layers.
